(19) United States
(12) Patent Application Publication
(10) Pub. No.: US 2026/0213688 A1
(43) Pub. Date: Jul. 23, 2026

(54) MICROELECTROMECHANICAL SYSTEM WITH ANALOG DEMODULATION AND DIGITAL DRIVE CONTROL

(71) Applicant: Robert Bosch GmbH, Stuttgart (DE)

(72) Inventors: Victor De Sousa Cavalcante, Muenchen (DE); Antonios Nikas, Kanagawa-Ken (JP); Francesco Diazzi, Muenchen (DE); Ruslan Khalilyulin, Muenchen (DE)

(21) Appl. No.: 19/439,652

(22) Filed: Jan. 5, 2026

(30) Foreign Application Priority Data
Jan. 20, 2025 (DE) 10 2025 101 773.5

(51) Int. Cl. H02P 23/14

(52) U.S. Cl. CPC H02P 23/14

(57) ABSTRACT

A microelectromechanical system with a micromechanical rotation rate sensor and at least one drive control unit. The micromechanical rotation rate sensor includes a drive unit. The at least one drive control unit includes a first part. The first part includes at least one demodulation unit, wherein analog demodulation of at least one analog feedback signal of the drive unit can be carried out by the at least one demodulation unit of the first part of the drive control unit.

### CROSS REFERENCE

The present application claims the benefit under 35 U.S.C. § 119 of Germany Patent Application No. DE 10 2025 101 773.5 filed on January 20, 2025, which is expressly incorporated herein by reference in its entirety.

### FIELD

The present invention proceeds from a microelectromechanical system (hereinafter also referred to as MEMS) with a micromechanical rotation rate sensor and at least one drive control unit.

### BACKGROUND INFORMATION

Micromechanical rotation rate sensors detect rotations or rotation rates about one or more sensor axes by evaluating deflections of mechanical structures or forces acting on a mechanical structure or on multiple mechanical structures or on one or more sensor elements, usually by means of capacitive detection devices. Specifically, this detection is typically carried out by multiple capacitors or capacitor arrangements, which are formed by electrode structures and possibly a part or parts of the sensor element(s), wherein the relevant spacing, for example the electrode spacing, affects the capacitance or the capacitance value of the capacitor arrangements so that the (relative) position of the mechanical structure or of the sensor element(s), in particular to electrode structures fixed to the substrate, can be determined thereby. Such a detection device is thus able to detect a change in the electrode spacing caused by a movement of the mechanical structure or of the sensor element, on the basis of a change in the capacitance. The latter is proportional (in the linear range) to the external physical stimulus or the deflection of the sensor element.

Modern microelectromechanical systems, cf. U.S. Patent Application No. US 2022/074746 A1, U.S. Patent Nos. US 10,107,625 B2 and US 8,508,290, and U.S. Patent Application No. US 2020/003560, includes drive control units in which both an amplitude control loop and a phase control loop are implemented analogously or in which demodulation of detection signals or feedback signals of the drive unit of a sensor is carried out digitally, which results in a high space requirement for electronic components and/or a high energy requirement due to the high-frequency, digital circuit operation.

### SUMMARY

It is an object of the present invention to provide a microelectromechanical system that comprises a micromechanical rotation rate sensor and at least one drive control unit and does not have the aforementioned disadvantages.

The microelectromechanical system according to the present invention with a micromechanical rotation rate sensor and at least one drive control unit has the advantage over the related art that it carries out the demodulation of detection signals of the rotation rate sensor and the demodulation of feedback signals of a drive unit of the rotation rate sensor analogously and, as a result, has a comparatively low power consumption and at the same time comprises an at least partially digitally implemented amplitude control loop and an at least partially digitally implemented phase control loop and is therefore more space-saving.

Advantageous embodiments and developments of the present invention can be found in the disclosure herein.

According to an advantageous example embodiment of the present invention, it is provided that the drive control unit of the microelectromechanical system is at least partially implemented as an ASIC.

According to another advantageous example embodiment of the present invention, it is provided that the amplitude control loop, in particular a digital part of the amplitude control loop, and/or the phase control loop, in particular a digital part of the phase control loop, is used to generate a drive signal of the drive unit, wherein the drive signal is in particular a sinusoidal signal.

According to another advantageous example embodiment of the present invention, it is provided that an analog rate signal and/or analog quadrature signal generated from analog demodulation of a detection signal of the rotation rate sensor is first low-pass filtered by means of at least one low-pass digital-to-analog converter and then converted into a digital rate signal and/or into a digital quadrature signal.

According to another advantageous example embodiment of the present invention, it is provided that a first analog signal and/or a second analog signal generated from analog demodulation of a feedback signal of the drive unit is first low-pass filtered by means of at least one low-pass digital-to-analog converter and then converted into a first digital feedback signal and/or into a second digital feedback signal.

According to another advantageous example embodiment of the present invention, it is provided that the amplitude control loop, in particular a digital part of the amplitude control loop, and/or the phase control loop, in particular a digital part of the phase control loop, is operable with a degree of utilization or degree of modulation of less than 100% and/or is operable in particular during a time fraction of the entire operating time of the microelectromechanical system, preferably during a time fraction that is less than the total operating time of the microelectromechanical system.

According to another advantageous example embodiment of the present invention, it is provided that a readout circuit, in particular a C/V converter, is used to convert a capacitance of a variable capacitor formed by drive electrodes of the micromechanical rotation rate sensor into an analog feedback signal dependent on the capacitance, in particular proportional to the capacitance.

According to another advantageous example embodiment of the present invention, it is provided that a further readout circuit, in particular a further C/V converter, is used to convert a further capacitance of a variable further capacitor formed by detection electrodes of the rotation rate sensor into a detection signal dependent on the further capacitance, in particular proportional to the further capacitance.

According to another advantageous example embodiment of the present invention, it is provided that the microelectromechanical system comprises the components used to generate a compensated rotation rate signal from the detection signal of a sensor axis (in particular an X-axis), multiple times and substantially identically, in particular for generating a further compensated detection signal from a further detection signal of a further sensor axis (in particular a Y-axis) and/or in particular for generating an additional compensated detection signal from an additional detection signal of an additional sensor axis (in particular a Z-axis), wherein the multiplicity of the substantially identical components is in particular equal to the number of sensor axes of the MEMS rotation rate sensor.

Exemplary embodiments of the present invention are shown in the figures and explained in more detail in the following description.

### BRIEF DESCRIPTION OF THE DRAWINGS

FIG. 1 shows a schematic representation of a microelectromechanical system according to the present invention according to a first embodiment of the present invention with analog demodulation and an at least partially digital amplitude control loop as well as an at least partially digital phase control loop.

FIG. 2 shows a schematic representation of a generally conventional microelectromechanical system with a drive control unit with analog demodulation and an analog amplitude control loop as well as an analog phase control loop.

FIG. 3 shows a schematic representation of a microelectromechanical system according to a second example embodiment of the present invention with a drive control unit with digital demodulation and a digital amplitude control loop as well as a digital phase control loop.

### DETAILED DESCRIPTION OF EXAMPLE EMBODIMENTS

The same parts in the various figures are always provided with the same reference signs and are therefore usually named or mentioned only once.

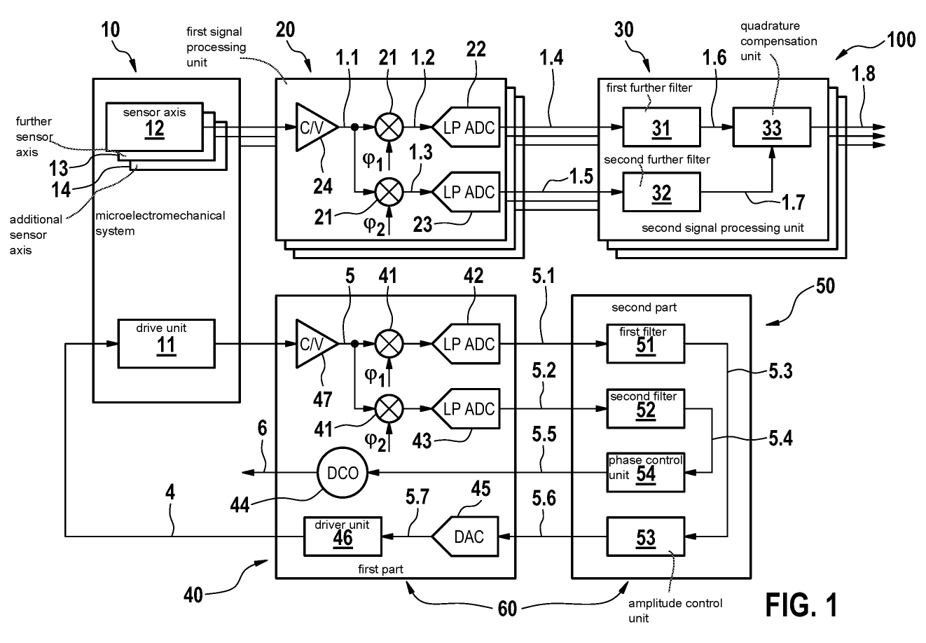

FIG. 1 shows a schematic representation of a microelectromechanical system 100 according to the present invention in a first embodiment with a micromechanical rotation rate sensor 10 and a drive unit 11 as well as a sensor axis 12 (corresponding to an X-axis), a further sensor axis 13 (corresponding to a Y-axis), and an additional sensor axis 14 (corresponding to a Z-axis). The micromechanical system 100 comprises a drive control unit 60, which comprises a first part 40 and a second part 50. A driver unit 46 of the first part 40 generates a drive signal 4 through which the drive unit 11 is set into periodic oscillation. The resulting changes in the spacing between drive electrodes of the drive unit 11 cause a periodically changing capacitance of a capacitor formed by the drive electrodes. A readout circuit 47, in particular a C/V converter, converts a periodically changing capacitance of the variable capacitor thus formed into an analog feedback signal 5 dependent on the capacitance, in particular proportional to the capacitance. The analog feedback signal 5 is broken down into a first analog signal and a second analog signal by an analog first demodulation carried out by means of a demodulation unit 41 and by an analog second demodulation carried out in particular in parallel in time and/or space, wherein the first analog signal is phase-shifted relative to the second analog signal, wherein the relative phase shift between the first and the second analog signal is in particular 90° or -90° or equal to the sum of an integer multiple of 360° and 90° or equal to the sum of an integer multiple of 360° and -90°. Thereafter, the first analog signal is first low-pass filtered by a first low-pass analog-to-digital converter 42 and then converted into a first digital feedback signal 5.1. The second analog signal is first low-pass filtered by a second low-pass analog-to-digital converter 43 and then converted into a second digital feedback signal 5.2. Thereafter, the first and second digital feedback signals 5.1, 5.2 are filtered by a first and a second filter 51, 52, respectively, of a second part 50 of the drive control unit 60, whereby a first filtered digital feedback signal 5.3 and a second filtered digital feedback signal 5.4 are generated, respectively. The first filtered digital feedback signal 5.3 is used as an input signal of an amplitude control unit 53, and the second filtered digital feedback signal 5.4 is used as an input signal of a phase control unit 54. From the first filtered digital feedback signal 5.3, the amplitude control unit 53 generates a digital amplitude control signal 5.6, which is converted into an analog amplitude control signal 5.7 by a digital-to-analog converter 45. The analog amplitude control signal 5.7 serves as an input signal of a driver unit 46, which then outputs a drive signal 4 of the drive unit 11, whereby the drive unit 11 is set into a controlled mechanical oscillation. From the second filtered digital feedback signal 5.4, the phase control unit 54 generates a phase control signal 5.5, which is used as a control signal of a digitally controlled oscillator 44. From the phase control signal 5.5, the digitally controlled oscillator 44 generates a clock signal 6 (in particular a clock signal 6 of the drive unit 11). The micromechanical rotation rate sensor 10 comprises at least one detection mass, which is set into mechanical oscillation by the drive unit 11. Depending on the likewise oscillating velocity, during a rotation of the microelectromechanical system 100 about the X-axis and/or the Y-axis and/or the Z-axis, Coriolis forces arise, which oscillate in the co-rotating reference system of the microelectromechanical system 100 and cause periodic changes in the spacing between detection electrodes of the micromechanical rotation rate sensor 10. In a first signal processing unit 20 of the microelectromechanical system 100, a further readout circuit 24, in particular a further C/V converter, converts a periodically changing capacitance of the further, variable capacitor thus formed into a detection signal 1.1 dependent on the further capacitance, in particular proportional to the further capacitance. For compensating a quadrature error, which occurs as a result of a cross-coupling of the drive movement into the detection movement, the detection signal 1.1 is broken down into an analog rate signal 1.2 and into an analog quadrature signal 1.3 by a first analog demodulation carried out by means of a further demodulation unit 21 and by a second analog demodulation carried out by means of the further demodulation unit 21, in particular in parallel in time and/or space with the first analog demodulation, wherein the analog rate signal 1.2 is phase-shifted relative to the analog quadrature signal 1.3, wherein the relative phase shift between the analog rate signal 1.2 and the analog quadrature signal 1.3 is in particular 90° or -90° or in particular the sum of an integer multiple of 360° and 90° or in particular the sum of an integer multiple of 360° and -90°. The analog rate signal 1.2 is first low-pass filtered by a first further low-pass analog-to-digital converter 22 and then converted into a digital rate signal 1.4. The analog quadrature signal 1.3 is first low-pass filtered by a second further low-pass analog-to-digital converter 23 and then converted into a digital quadrature signal 1.5. In a second signal processing unit 30 of the microelectromechanical system 100, the digital rate signal 1.4 and the digital quadrature signal 1.5 are filtered thereafter by a first further and a second further filter 31, 32, respectively, whereby a filtered digital rate signal 1.6 and a filtered digital quadrature signal 1.7 are generated, respectively. A quadrature compensation unit 33 generates a compensated detection signal 1.8 from the filtered digital rate signal 1.6 and/or from the filtered digital quadrature signal 1.7, wherein the compensated detection signal 1.8 is used to calculate the rotation rate of a rotation of the microelectromechanical system 100, in particular a rotation of the microelectromechanical system 100 about an X-axis and/or about a Y-axis and/or about a Z-axis.

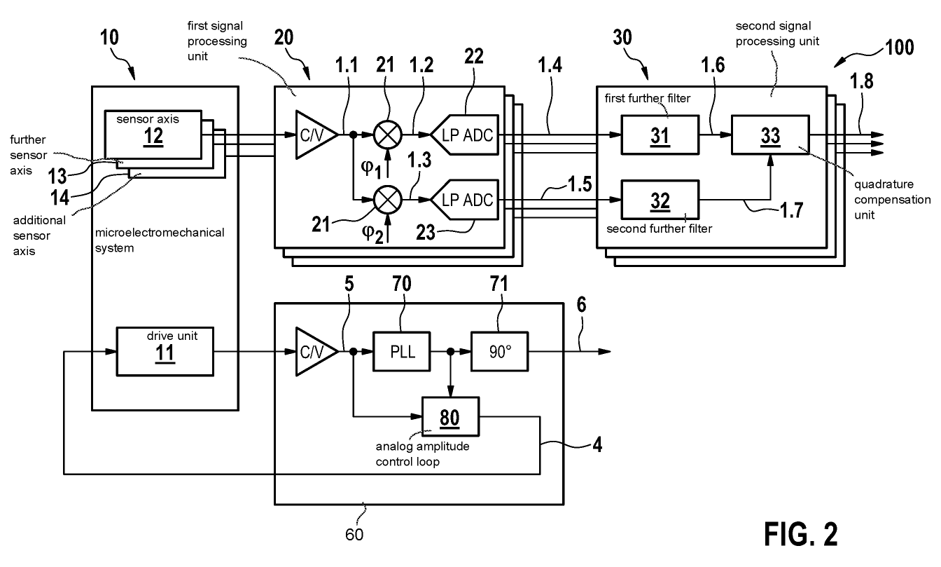

FIG. 2 shows a schematic representation of a generally conventional microelectromechanical system 100 with a drive control unit 60 with analog demodulation and an analog phase control loop 70 as well as an analog amplitude control loop 80. The drive control unit 60 also comprises a 90° phase shifter 71. From the analog feedback signal 5 of the drive unit 11, a clock signal 6, in particular a clock signal 6 for the drive unit 11, is generated in that, by using the analog feedback signal 5 as an input signal of the analog phase control loop 70 and subsequently using a thus generated output signal, in particular a control signal, of the analog phase control loop 70 as an input signal of a subsequent 90° phase shifter 71, the clock signal 6 is generated from the subsequent output signal of the 90° phase shifter 71. A drive signal 4 of the drive unit 11 results from the use of the analog amplitude control loop 80, wherein the analog feedback signal 5 of the drive unit 11 is in particular present as a first input signal of the analog amplitude control loop 80 and/or the control signal of the analog phase control loop 70 is present as a second input signal of the analog amplitude control loop 80, and the drive signal 4 of the drive unit 11 results from the control signal of the analog amplitude control loop 80.

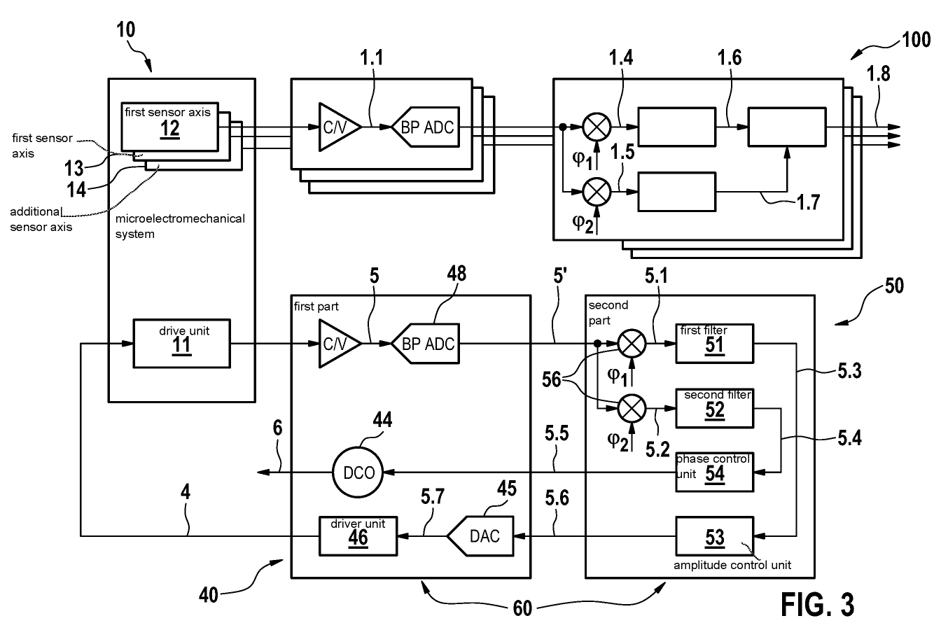

FIG. 3 shows a schematic representation of a microelectromechanical system 100 according to the present invention in a second embodiment with a drive control unit 60, which comprises a digital demodulation unit 56 and a digital amplitude control loop as well as a digital phase control loop. Digital demodulation of a digital output signal 5' is carried out, wherein a bandpass analog-to-digital converter 48 generates the digital output signal 5' from the analog feedback signal 5.

The present invention is not limited to the above-described exemplary embodiments, but can be used in a variety of applications for inertial-sensor-based navigation, orientation, and stabilization of objects. Via a computing unit in the sensor, the operation of the inertial sensor can be controlled (e.g., power-saving mode, measuring ranges), sensor signals can be made plausible and checked for, e.g., tolerances (e.g., for internal sensor monitoring), signal processing can occur (e.g., calculation of the position or orientation, filtering of the data), and communication protocols can be selected. Various, even self-learning, AI-based algorithms can be used in the computing unit for the evaluation and signal processing of the data of the inertial sensors, of the temperature sensors, as well as external data (e.g., GPS data, odometer data). Exemplary areas of application can be found in:

automotive applications (e.g., ESP, rollover sensing, airbag, road noise cancellation, theft alert system, parking dents, road condition monitoring)

in two-wheeled vehicles, e.g., motorcycle, bicycle, roller applications (e.g., in ESP/airbag, inclination detection, balancing)

in three-wheeled vehicles, such as TukTuks

in the avionics field (e.g., in flight stabilization and flight control)

in industrial robot applications (e.g., in position control of excavator buckets, drilling, image stabilization, flight control, satellite antenna alignment, fine motor skills in robot gripping)

in home and garden applications (e.g., in lawnmower navigation, door position monitoring)

in medical applications (e.g., fall detection, movement and posture detection)

in sports and recreational applications (e.g., movement detection, posture detection, for golf clubs, tennis rackets, or skis)

in numerous consumer applications, e.g., in smartphones, tablets, wearables, hearables, drones, gaming toys, AR or VR

Numerous configurations, changes, modifications, deviations, variations, and embodiments are also possible; all of which fall within the scope of the present invention.

What is claimed is:

1. A microelectromechanical system, comprising:
a micromechanical rotation rate sensor; and
at least one drive control unit;
wherein the micromechanical rotation rate sensor includes a drive unit, and
wherein the at least one drive control unit includes a first part, the first part includes at least one demodulation unit, wherein the at least one demodulation unit of the first part of the at least one drive control unit is configured to carry out analog demodulation of at least one analog feedback signal of the drive unit.

2. The microelectromechanical system according to claim 1, wherein the at least one demodulation unit is configured to carry out a first analog demodulation of the analog feedback signal and/or a second analog demodulation of the analog feedback signal.

3. The microelectromechanical system according to claim 2, wherein the first analog demodulation is carried out with a first phase shift and/or the second analog demodulation is carried out with a second phase shift, and wherein the first phase shift is 0° and/or the second phase shift is 90°.

4. The microelectromechanical system according to claim 1, wherein the first part of the at least one drive control unit includes at least one low-pass analog-to-digital converter.

5. The microelectromechanical system according to claim 3, wherein the at least one low-pass analog-to-digital converter includes a first low-pass analog-to-digital converter and a second low-pass analog-to-digital converter.

6. The microelectromechanical system according to claim 5, wherein the at least one demodulation unit is configured to carry out a first analog demodulation of the analog feedback signal and/or a second analog demodulation of the analog feedback signal, wherein the first analog demodulation can be carried out with a first phase shift and/or the second analog demodulation can be carried out with a second phase shift, wherein the first phase shift is 0° and/or the second phase shift is 90°, and wherein a first analog signal generated by the first analog demodulation can be converted into a first digital feedback signal by the first low-pass analog-to-digital converter and/or a second analog signal generated by the second analog demodulation can be converted into a second digital feedback signal by the second low-pass analog-to-digital converter.

7. The microelectromechanical system according to claim 6, wherein the drive control unit includes a second part, wherein the second part includes at least one filter including a first filter and a second filter, wherein the first filter generates a first filtered digital feedback signal from the first digital feedback signal and/or the second filter generates a second filtered digital feedback signal from the second digital feedback signal.

8. The microelectromechanical system according to claim 7, wherein the second part includes an amplitude control unit and/or a phase control unit, wherein the amplitude control unit is configured to generate a digital amplitude control signal from the first filtered digital feedback signal and/or the phase control unit is configured to generate a phase control signal from the second filtered digital feedback signal.

9. The microelectromechanical system according to claim 8, wherein the first part of the at least one drive control unit includes a digitally controlled oscillator and/or a digital-to-analog converter and/or a driver unit, wherein: (i) the digitally controlled oscillator is configured to generate a clock signal from the phase control signal and/or (ii) the digital-to-analog converter is configured to generate an analog amplitude control signal from the digital amplitude control signal, and the driver unit is configured to generate a drive signal of the drive unit at least from the analog amplitude control signal.

10. The microelectromechanical system according to claim 1, wherein the micromechanical rotation rate sensor includes at least one sensor axis, a further sensor axis, and an additional sensor axis, wherein the sensor axis corresponds to an X-axis and/or the further sensor axis corresponds to a Y-axis and/or the additional sensor axis corresponds to a Z-axis.

11. The microelectromechanical system according to claim 10, wherein the microelectromechanical system further comprises a first signal processing unit, wherein the first signal processing unit includes at least one further demodulation unit, wherein the at least one further demodulation unit is configured to carry out a first analog demodulation of a detection signal of the sensor axis and/or a second analog demodulation of the detection signal of the sensor axis, wherein the first analog demodulation of the detection signal can be carried out with a first phase shift and/or the second demodulation of the detection signal can be carried out with a second phase shift, wherein the first phase shift is in particular 0° and/or the second phase shift is in particular 90°, wherein the first analog demodulation of the detection signal can generate an analog rate signal from the detection signal and/or the second analog demodulation of the detection signal can generate an analog quadrature signal from the detection signal.

12. The microelectromechanical system according to claim 11, wherein the first signal processing unit includes at least one further low-pass analog-to-digital converter including a first further low-pass analog-to-digital converter and a second further low-pass analog-to-digital converter, wherein the first further low-pass analog-to-digital converter is configured to generate a digital rate signal from the analog rate signal and/or the second further low-pass analog-to-digital converter is configured to generate a digital quadrature signal from the analog quadrature signal.

13. The microelectromechanical system according to claim 12, wherein the microelectromechanical system further comprises a second signal processing unit, wherein the second signal processing unit includes at least one further filter including a first further filter and a second further filter, wherein the second signal processing unit includes a quadrature compensation unit, wherein the first further filter is configured to generate a filtered digital rate signal from the digital rate signal and/or the second further filter is configured to generate a filtered digital quadrature signal from the digital quadrature signal, wherein the quadrature compensation unit is configured to generate a compensated detection signal from the filtered digital rate signal and/or from the filtered digital quadrature signal.
